(19) United States
(12) Patent Application Publication
(10) Pub. No.: US 2006/0137607 A1
(43) Pub. Date: Jun. 29, 2006

(54) Combination of showerhead and temperature control means for controlling the temperature of the showerhead, and deposition apparatus having the same

(76) Inventors: Jung-Hun Seo, Suwon-si (KR); Young-Wook Park, Suwon-si (KR); Jin-Gi Hong, Suwon-si (KR); Kyung-Bum Koo, Yongin-si (KR); Eun-Taeck Lee, Suwon-si (KR); Yun-Ho Choi, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/317,092

(22) Filed: Dec. 27, 2005

(30) Foreign Application Priority Data
Dec. 27, 2004 (KR) 2004-112845

(51) Int. Cl. C23C 16/00; C23F 1/00; H01L 21/306

(52) U.S. Cl. 118/715; 156/345.37; 156/345.34

(57) ABSTRACT

A chemical vapor deposition apparatus has a showerhead, and temperature control apparatus including a heater and a heat dissipation plate for regulating the temperature of the showerhead. The showerhead includes a bottom plate having gas spray openings, and an upper plate. The heater is disposed on an upper plate of the showerhead. The heat dissipation plate contacts an upper portion of the upper plate of the showerhead above the heater so that heat dissipates from the showerhead through the plate. The temperature control apparatus also includes a coolant system by which coolant is fed into a space defined between the heater and the heat dissipation plate. The temperature of the showerhead is precisely controlled using the heater, the heat dissipation plate and the coolant system.

### BACKGROUND OF THE INVENTION

1. Field of the Invention

The present invention relates to an apparatus for controlling a temperature of a showerhead and an apparatus for forming a layer having the same. More particularly, the present invention relates to an apparatus for controlling a temperature of a showerhead that is capable of adjusting the temperature of the showerhead to a desired temperature and an apparatus for forming a layer having the apparatus for controlling a temperature of a showerhead.

2. Description of the Related Art

In general, semiconductor devices are manufactured by a fabrication process for forming electrical circuits on a semiconductor substrate such as a silicon wafer, an electrical die sorting (EDS) process for inspecting electrical characteristics of the semiconductor devices, and a package assembling process for dividing the semiconductor substrate into parts each comprising a semiconductor device and encapsulating each of the semiconductor devices using epoxy resin.

The fabrication process comprises a plurality of individual processes that are performed in sequence. For example, the fabrication process will typically include a deposition process for forming a layer on the silicon wafer, a chemical mechanical polishing (CMP) process for planarizing the layer, a photolithography process for forming a photoresist pattern on the layer, an etching process for etching the layer using the photoresist pattern as an etching mask to form a pattern having an electrical characteristic, an ion implantation process for implanting impurities into a predetermined region of the silicon wafer, a cleaning process for removing particles attached to the silicon wafer, and an inspection process for inspecting a surface of the silicon wafer on which the layer and/or pattern is formed. Each semiconductor device typically has a multi-layered structure formed by repeatedly subjecting the semiconductor substrate to these processes a number of times.

Specifically, a semiconductor device will have several metal wiring layers, i.e., conductive wiring on several layers on the semiconductor substrate. The wiring on adjacent ones of the wiring layers will be connected by forming a contact hole between the wiring layers, and filling the contact hole with metal such as titanium (Ti), aluminum (Al), or copper (Cu) or a metal compound such as tungsten silicide (WSi), titanium nitride (TiN), or titanium silicide (TiSix). The aforementioned deposition process is used to fill such a contact hole. A similar deposition process is also used to form a barrier layer that prevents interactions from occurring between another metal layer and a semiconductor layer, for example.

Generally, these types of metal layers or the metal compound layers are formed by a physical vapor deposition (PVD) process or a chemical vapor deposition (CVD) process. However, the PVD process has shown poor ability to form layers that can fill the gaps, such as contact holes, required in fabricating today's highly integrated semiconductor devices whose design rule is ever become smaller and smaller. The CVD process has a much better gap-filling characteristic. Thus, CVD has been widely employed to form metal layers in the fabricating of semiconductor devices.

A conventional method of and apparatus for forming a titanium layer using CVD will now be described in detail.

The apparatus includes a chamber having a first heater, and a wafer stage into which a second heater is built. A showerhead is installed in an upper portion of the chamber for providing a processing gas into the process chamber. The showerhead faces the wafer stage.

The chamber is heated to a predetermined temperature and a vacuum is produced in the chamber. A semiconductor wafer mounted on the wafer stage is heated to a desired temperature using the second heater. The processing gas, such as TiCl₄ gas and H₂, is then introduced into the chamber through the showerhead. Radio frequency (RF) power is applied to the showerhead to transform the processing gas into plasma. The plasma impinges the semiconductor wafer, thereby forming a titanium layer on the semiconductor wafer

Recently, larger semiconductor wafers are being used in the production of semiconductor devices. The diameter of a semiconductor wafer may now be about 300 mm or greater. Thus, the CVD apparatus are becoming larger to accommodate these larger diameter semiconductor wafers.

The showerhead of a CVD apparatus is heated by the radiant heat generated by the second heater disposed in the wafer stage. The radiant heat causes local variations in the surface temperature of the showerhead. If left unchecked, these local variations in the surface temperature of the showerhead would cause corresponding variations in the thickness of the layer formed on the silicon wafer. Accordingly, the temperature of the showerhead must be stabilized before the CVD process is performed on the silicon wafer. However, the amount of radiant heat now absorbed by a showerhead of a conventional CVD apparatus has increased along with the increase in size of the apparatus. Accordingly, a comparatively long period of time is required for stabilizing the temperature of the showerhead, which detracts from the efficiency of the process.

Also, it is especially important to precisely control the temperature of the showerhead when forming a layer such as a titanium (Ti) layer or a titanium nitride (TiN) layer on a silicon wafer using TiCl₄. However, the conventional CVD apparatus suffer from the following drawbacks associated with the temperatures that prevail in the apparatus.

A plasma enhanced chemical vapor deposition (PECVD) apparatus is used for forming a Ti layer on a silicon wafer. In this process, it is desirable to preliminarily coat the showerhead with a layer of Ti before the PECVD process is carried out to form a layer of Ti or TiN on a semiconductor wafer. At this time, the temperature of the showerhead must be at least about 400° C. if the Ti layer is to sufficiently adhere to the showerhead. Therefore, in addition to the heater in the wafer stage, the PECVD apparatus includes a showerhead heater for heating the showerhead to a temperature of at least about 400° C. (about 400° C. to about 450° C.) so that the showerhead can be coated with a layer of Ti before a Ti layer is formed on the wafer. For example, the surface of the showerhead can be heated to at least about 400° C. when the temperature of the showerhead heater is about 300° C. and the temperature of the second heater is at least about 600° C.

However, an O-ring that creates a seal between a lid of the PECVD apparatus and the sidewall of the chamber of the apparatus deteriorates when the temperature of the O-ring is higher than about 280° C. The temperature of the O-ring becomes greater than 280° C. when the surface temperature the showerhead is about 400° C. When the O-ring is broken or damaged, gases leak from the chamber. Thus, in a PECVD apparatus, a layer of Ti that sufficiently adheres to the showerhead can not be formed without severely compromising the air-tightness of the chamber.

In apparatus for forming a TiN layer on a silicon wafer, the TiCl₄ is thermally decomposed. In this case, though, the temperature of the showerhead must be no more than about 250° C. to prevent the thermally decomposed TiCl₄ from forming a layer of titanium nitride on the showerhead.

However, it is very difficult to maintain the temperature of the showerhead below about 250° C. Specifically, in the forming of a TiN layer on a silicon wafer, the second heater heats the wafer stage on which the silicon wafer is disposed to a temperature of about 400° C. to about 700° C. When the temperature of the second heater is about 530° C., the radiant heat generated from the wafer stage increases the surface temperature of the showerhead to about 260° C. As a result, titanium nitride is deposited on the surface of the showerhead. As mentioned above, titanium will not adhere well to the showerhead when the temperature of the showerhead during the time of deposition is less than about 400° C. Therefore, particles of the titanium nitride deposited on the showerhead during the process of forming the TiN layer on the wafer can subsequently flake off of the showerhead and thereby contaminate the wafer or other wafers that are subsequently processed in the chamber.

### SUMMARY OF THE INVENTION

An object of the present invention is to overcome the drawbacks and disadvantages of the prior art.

A more specific object of the present invention is to provide means for precisely controlling the temperature of a showerhead of an apparatus for processing a substrate using gas.

According to one aspect of the present invention, the present invention provides the combination of a showerhead, and apparatus for controlling the temperature of the showerhead wherein the apparatus includes a heater for heating the showerhead and a heat dissipation plate by which heat is dissipated from the showerhead. The showerhead has a bottom plate defining a plurality of spray openings through which gas is sprayed from the showerhead uniformly. The heater is disposed on the showerhead, preferably on an upper plate of the showerhead. The heat dissipation plate is disposed in contact with a portion the showerhead to absorb heat from the showerhead. The heater is located between the bottom plate of the showerhead and the heat dissipation plate.

In accordance with another aspect of the present invention, the present invention provides a deposition apparatus for forming a layer on the substrate, which incorporates the combination of a showerhead, showerhead heater and heat dissipation plate. The deposition apparatus also includes a processing chamber in which the process for forming a layer on the substrate takes place, a stage for supporting the substrate in the processing chamber, and a gas-supplying unit that provides a reaction gas used for forming the layer. The showerhead is disposed in an upper portion of the processing chamber, and is connected to the gas-supplying unit so that the reaction gas is introduced into the process chamber via the showerhead.

According to the present invention, the temperature of the showerhead is controlled so that a layer of material that adheres well tot eh showerhead may be formed on the showerhead prior to the deposition process. Thus, the layer of material formed on the showerhead will not generate particles within the process chamber. Furthermore, the temperature of the showerhead may be controlled to prevent an O-ring that creates a seal between a lid and the process chamber of the apparatus from deteriorating.

According to yet another aspect of the present invention, the apparatus for controlling the temperature of the showerhead may further include a coolant system. In this case, a space is defined between the heater and the heat dissipation plate, and the coolant system includes a cooling line extending into the space. Thus, coolant for cooling the showerhead is fed through the cooling line into the space defined between the heater and the heat dissipation plate.

Therefore, the temperature of the showerhead can be lowered rapidly to ready the apparatus for being cleaned.

Still further, the apparatus for controlling the temperature of the showerhead allows the surface temperature of the showerhead to be stabilized quickly and maintained uniform during the deposition process. Accordingly, a layer having a uniform thickness can be formed on a substrate.

### BRIEF DESCRIPTION OF THE DRAWINGS

The above and other objects, features and advantages of the present invention will become more apparent from the following detailed description of the preferred embodiments thereof made with reference to the accompanying drawings, in which:

FIG. 1 is a cross-sectional view of an apparatus for forming a Ti layer in accordance with the present invention;

FIG. 2 is a plan view of the apparatus illustrated in FIG. 1; and

FIG. 3 is a cross-sectional view of the combination of a showerhead and elements by which the temperature of the showerhead can be controlled in accordance with the present invention.

### DETAILED DESCRIPTION OF THE PREFERRED EMBODIMENTS

A CVD apparatus for forming a titanium (Ti) layer or the like on a substrate will now be described in detail with reference to the drawings.

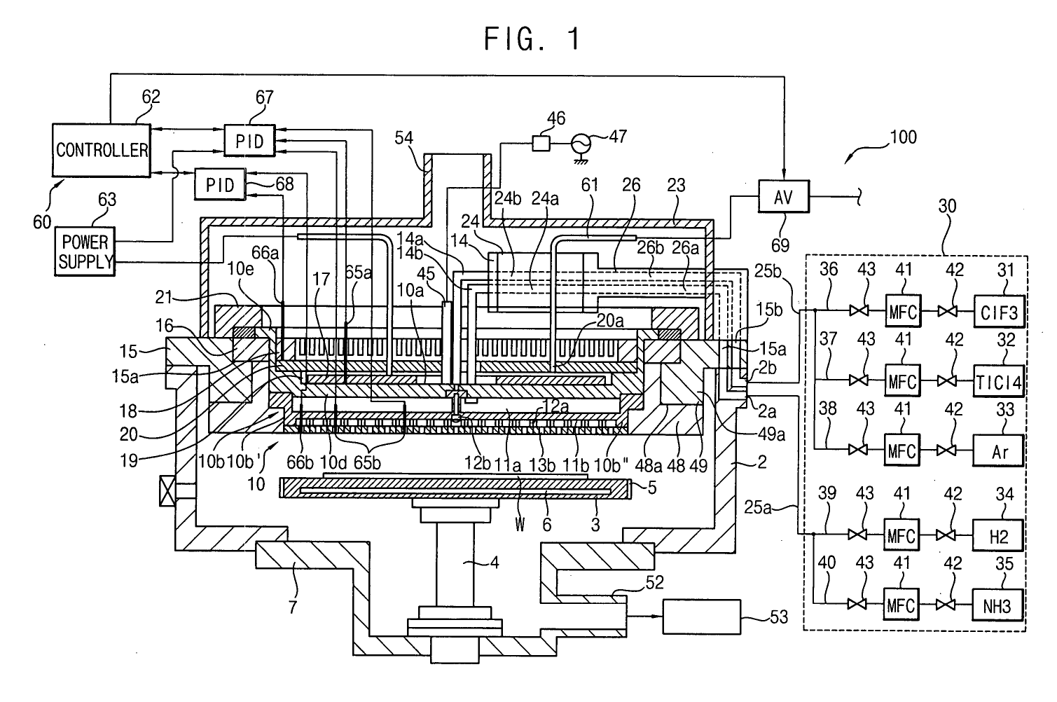

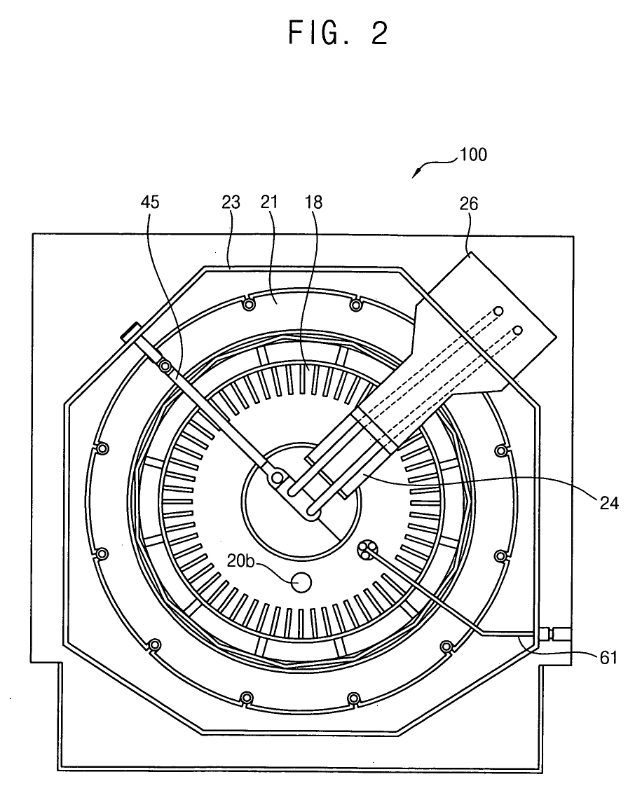

Referring first to FIGS. 1 and 2, the apparatus 100 includes a cylindrical or hexahedral chamber 2. A stage 3 is disposed in the chamber 2. The stage 3 supports a semiconductor wafer W horizontally. A stage-supporting member 7 is mounted to a central portion of the bottom of the chamber 2 and protrudes downwardly from the bottom of the chamber 2. A seal (not shown) is interposed between the bottom surface of the chamber 2 and the stage-supporting member 7. A cylindrical shaft 4 has an upper end fixed to a bottom surface of the stage 3 and a lower end secured to an upper surface of the stage-supporting member 7.

The chamber 2 and the stage-supporting member 7 may include a heating unit (not shown). Power is applied to the heating unit from a power supply (not shown) so that the chamber 2 and the stage-supplying member 7 are heated to a predetermined temperature.

A ring 5 for focusing a stable supply of plasma onto the stage 3 extends along the outer periphery of the stage 3. Furthermore, a stage heater 6 for heating the stage 3 is built into the stage 3. Power is applied from a power supply (not shown) to the stage heater 6 so that the semiconductor wafer W is heated to a predetermined temperature on the stage 3.

Referring now to FIGS. 1 to 3, the apparatus 100 also includes a showerhead 10 disposed in an upper portion of the chamber 2. The showerhead 10 faces the stage 3. The showerhead 10 includes an upper plate 10a, a middle plate 10b, and a lower plate 10c.

The upper plate 10a has a horizontal portion 10d for defining a body of the showerhead 10 together with the middle plate 10b and the lower plate 10c, and an annular supporting portion 10e extending vertically from the periphery of the horizontal portion 10d. The upper plate 10a thus is concave or bowl-shaped. As shown in FIGS. 1 to 3, a plurality of ribs 10f extends from an inner surface of the annular supporting portion 10e by no less than about 5 mm, and preferably by no less than about 10 mm, towards the center of the showerhead 10. Also, in this example embodiment, the ribs 10f have a width of no less than about 2 mm, and preferably no less than about 5 mm, and are spaced apart from each other by substantially identical intervals. Although the annular supporting portion 10e is relatively thin, the strength of the annular supporting portion 10e is enhanced by the ribs 10f. Thus, the annular supporting portion 10e is resistant to being deformed by heat generated in the apparatus. As a result, heat is prevented from dissipating from the showerhead 10.

The middle plate 10b is also concave or bowl-shaped. The upper plate 10a functions as a base for the middle plate 10b. An upper part of the outer portion of the middle plate 10b is fastened by screws, or the like, to the outer part of the horizontal portion 10d of the upper plate 10a. Furthermore, the middle plate 10b is fastened by screws, or the like, to the lower plate 10c with the upper surface of the lower plate 10c bearing against the lower surface of the middle plate 10b.

A first enclosed space 11a is formed between a lower surface of the horizontal portion 10d of the upper plate 10a and an upper surface of the middle plate 10b. A plurality of annular grooves extend in the lower surface of the middle plate 10b as spaced radially from each other by substantially identical intervals, and the annular grooves are connected to each other by grooves (not shown) extending radially in the lower surface of the middle plate 10b. A second space 11b is defined by the grooves in the lower surface of the middle plate 10b.

The middle plate 10b has a plurality of first gas passages 12a. The first gas passages 12a extend through the middle plate 10b and thus, are in communication with the first space 11a. In this example embodiment, the first gas passages 12a are each located between adjacent ones of the annular grooves in the lower surface of the middle plate 10b. A first gas is supplied from the space 11a to the first gas passages 12a.

A second gas passage 12b is in communication with the second space 11b. The second gas passage 12b extends through a tubular connecting member 12a′. The connecting member 12a′ is connected between the upper plate 10a and the middle plate 10b. More specifically, the connecting member 12a′ has an upper end integrated with a central portion of the lower surface of the upper plate 10a, and a lower end integrated with a central portion of the middle plate 10b. A second gas is supplied through the second gas passage 12b to the space 11b.

The lower plate 10c has first gas spraying holes 13a that are connected to the first gas passages 12a, respectively, and second gas spraying holes 13b that are connected to the space 11b.

The diameter of the first gas passages 12a in the middle plate 10b is, for example, about 0.5 mm to about 3 mm, and preferably about 1.0 mm to about 2.0 mm. In addition, the first gas spraying holes 13a each have a stepped configuration. More particularly, each first gas spraying hole 13a has a first portion and a second portion contiguous to the first portion with the diameter of the first portion being larger than that of the second portion. For example; the diameter of the first portion of the gas spraying hole 13a is about 1.0 mm to about 3.5 mm, and preferably about 1.2 mm to about 2.3 mm, whereas, the diameter of the second portion of the gas spraying hole 13a is about 0.3 mm to about 1.0 mm, and preferably about 0.5 mm to about 0.7 mm.

A first gas introducing pipe 14a and a second gas introducing pipe 14b are connected to the upper plate 10a. The first and second gas introducing pipes 14a and 14b are in communication with the spaces 11a and 11b, respectively. Thus, the first gas fed through the first gas introducing pipe 14a is successively introduced into the space 11a and the first gas passages 12a and is then discharged from the first gas spraying holes 13a into the chamber 2. The second gas fed through the second gas introducing pipe 14b is introduced into the space 11b through the second gas passage 12b and is then discharged from the second gas spraying holes 13b into the chamber 2.

Thus, the first gas fed through the first gas introducing pipe 14a and the second gas fed through the second gas introducing pipe 14b are introduced into the chamber 2 independently of one another. That is, the first gas fed through the first gas introducing pipe 14a and the second gas fed through the second gas introducing pipe 14b are not mixed with each other in the showerhead 10. Such a showerhead 10 is referred to in the art as a matrix type of showerhead.

Referring again to FIG. 1, a second end portion of the first gas introducing pipe 14a and a second end portion of the second gas introducing pipe 14b are commonly welded to a flange 14. An insulation member 24 having a first gas passage 24a and a second gas passage 24b is coupled to a first end portion of the flange 14. The first gas introducing pipe 14a and the second gas introducing pipe 14b are connected to the first gas passage 24a and the second gas passage 24b, respectively.

A second end portion of the insulation member 24 is integrated with a gas-introducing member 26. The gas-introducing member 26 has a third gas passage 26a and a fourth gas passage 26b. The third and fourth gas passages 26a and 26b of the gas-introducing member 26 are connected to the first gas passage 24a and second gas passage 24b of the insulation member 24, respectively.

A cover member 15 integrated with the chamber 2 has a fifth gas passage 15a and a sixth gas passage 15b. The fifth gas passage 15a is connected to the third gas passage 26a and the sixth gas passage 15b is connected to the fourth gas passage 26b of the gas-introducing member 26.

A sidewall of the chamber 12 has a seventh gas passage 2a and an eighth gas passage 2b, respectively. The seventh gas passage 2a is connected to the fifth gas passage 15a and the eighth gas passage 2b is connected to the sixth gas passage 15b of the cover member 15.

Thus, the first gas supplied into the chamber 2 is fed through the first gas introducing pipe 14a from the first, third, fifth and seventh gas passages 24a, 26a, 15a and 2a. Seals, such as O-rings, are disposed around the first, third, fifth and seventh gas passages 24a, 26a, 15a and 2a at interconnected portions of the flange 14, insulation member 24, gas-introducing member 26, cover member 15, and sidewall of the chamber 12, respectively. Similarly, the second gas supplied into to the chamber 2 is fed through the second gas introducing pipe 14b from the second, fourth, sixth and eight gas passages 24b, 26b, 15b and 2b. Seals, such as O-rings, are disposed around the first, third, fifth and seventh gas passages 24b, 26b, 15b and 2b at the interconnected portions of the flange 14, insulation member 24, gas-introducing member 26, cover member 15, and sidewall of the chamber 12, respectively.

Furthermore, a first gas pipe 25a is connected to the seventh gas passage 2a of the chamber 2 and a second gas pipe 25b is connected to the eighth gas passage 2b of the chamber 2. End portions of the first and second gas pipes 25a and 25b are coupled to a gas-supplying unit 30, respectively. The gas-supplying unit 30 includes a source 31 of cleaning gas such as ClF₃, a source 32 of process gas such as TiCl₄, a source 33 of carrier gas such as argon, a source 34 of a reduction gas such as H₂, and a source 35 of a nitrifying gas such as a NH₃ which is used for nitrifying a Ti layer.

The gas-supplying unit 30 also includes a first gas pipe 36, a second gas pipe 37, a third gas pipe 38, a fourth gas pipe 39 and a fifth gas pipe 40. The first gas pipe 36, second gas pipe 37, and third gas pipe 38 are connected to the source 31 of cleaning gas, the source 32 of process gas and the source 33 of carrier gas, respectively. The first, second and third gas pipes 36, 37 and 38 are also coupled to the second gas pipe 25b. The fourth gas pipe 39 and the fifth pipe 40 are connected to the source 34 of reduction gas and the source 35 of nitrifying gas, respectively. The fourth and fifth gas pipes 39 and 40 are also coupled to the first gas pipe 25a. Accordingly, the second gas, which can be either the ClF₃, the TiCl₄ gas or the argon, is supplied from the second gas pipe 25b to the second gas introducing pipe 14b through the second, fourth, sixth, and eighth gas passages 24b, 26b, 15b and 2b. The first gas, which can be either the reduction gas or the nitrifying gas, is supplied from the first gas pipe 25 to the first gas introducing pipe 14a through the first, third, fifth, and seventh gas passages 24a, 26a, 15a and 2a.

Thus, the process gas and the reduction gas are separately introduced into the chamber 2 and are then mixed with each other in the chamber 2. The process gas and the reduction gas are reacted with each other to generate the plasma in the chamber 2, thereby forming a Ti layer on the semiconductor wafer W.

Mass flow controllers (MFCs) 41 are installed in the first, second, third, fourth, and fifth gas pipes 36, 37, 38, 39 and 40, respectively. Pairs of valves 42 and 43 are also installed in the first, second, third, fourth, and fifth pipes 36, 37, 38, 39 and 40, respectively. In addition, the gas-supplying unit 30 may include an N₂ source, and gas pipes, valves, etc associated therewith.

The cover member 15 is mounted on the chamber 2. The cover member 15 is annular and the inner peripheral portion thereof is stepped. A first annular insulation member 16 is disposed on the inner stepped portion of the cover member 15. The annular supporting portion 10e of the upper plate 10a is disposed on an upper surface of the first insulation member 16. A second annular insulation member 21 covers the upper plate 10a so that the temperature of the upper plate 10a is maintained. The cover member 15 supports the second insulation member 21. In this embodiment, the first insulation member 16 insulates the showerhead 10 from the sidewall of the chamber 2 and also prevents heat from dissipating to the sidewall of the chamber 2 from the showerhead 10. Seals, such as O-rings, are interposed between the chamber 2 and the cover member 15, the cover member 15 and the first insulation member 16, and the first insulation member 16 and the supporting member 10e, respectively, so that the chamber 2 is sealed from the external environment.

A heater 17 is disposed on the horizontal portion 10d of the upper plate 10a. The heater 17 faces the semiconductor wafer W on the stage 3. The heater 17 includes, for example, a pair of resistive heating elements in the form of thin plates and an insulating plate of mica interposed between the heating elements. The heater 17 constitutes an element of a showerhead temperature control unit.

A space 19 is formed over the heater 17. A third insulation member 20 is disposed over the space 19. Dry air for cooling the showerhead 10 circulates in the space 19. In the illustrated embodiment, although the space 19 for receiving the dry air is formed between the heater 17 and the third insulation member 20, such a space may instead be provided within the third insulation member 20.

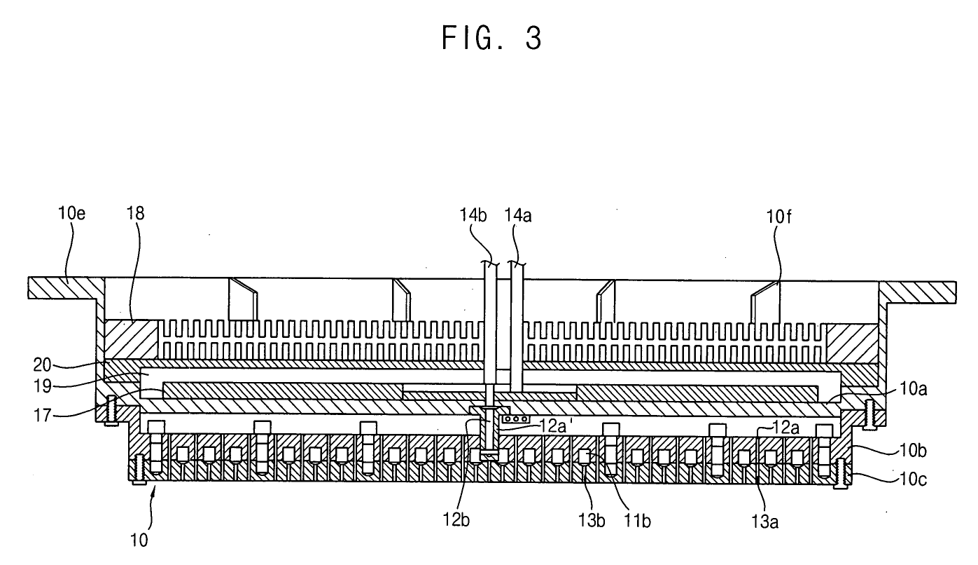

A heat dissipation plate 18 is disposed on the third insulation member 20. As best seen in FIGS. 2 and 3, the heat dissipation plate 18 is annular and extends along an outer peripheral portion of an upper part of the showerhead 10. The heat dissipation plate 18 may be made of aluminum (Al) or aluminum alloy, for example. Also, the heat dissipation plate has a plurality of fins that facilitate the transfer of heat from the plate to the surrounding air. Thus, the heat dissipation plate 18 uniformly distributes heat from the showerhead 10 and causes the heat to readily dissipate into the air in space 19.

The heat dissipation plate 18 thus also prevents the O-rings interposed between the chamber 2 and the cover member 15, the cover member 15 and the first insulation member 16, and the first insulation member 16 and the annular supporting member 10e from being overheated, i.e., the heat dissipation plate 18 prevents the O-rings from deteriorating. As a result, gases are prevented from leaking from the chamber 2.

The annular heat dissipation plate 18 described above as covering only an outer peripheral portion of the showerhead 10 is applicable to a plasma enhanced CVD apparatus for forming a Ti layer. In this case, a main purpose of the annular heat dissipation plate 18 is to prevent the O-rings from deteriorating. The present invention is also applicable to a thermal decomposition type of CVD apparatus for forming a TiN layer on a semiconductor wafer. In this case, the heat dissipation plate 18 should cover substantially the entire upper surface of the showerhead 10 to keep the temperature of the showerhead 10 to no more than about 250° C. Thus, the heat dissipation plate 18 will cool the showerhead 10 enough to prevent a TiN layer from forming on the showerhead 10, i.e., will prevent particles of TiN from being produced in the chamber 2.

The third insulation member 20 has a cooling gas passage 20a and an exhaust hole (not shown) extending therethrough in communication with the space 19. A dry air-supplying pipe 61 is connected to an upper portion of the cooling gas passage 20a. Dry air fed through the cooling gas passage 20a from the air-supplying pipe 61 circulates in the space 19 to cool the showerhead 10. After the showerhead 10 is cooled using the dry air, the dry air is exhausted to the exterior through the exhaust hole. In this embodiment, air has been described as the gas for cooling the showerhead 10. Alternatively, helium, argon, hydrogen, or nitrogen alone or in a mixture thereof may be used for cooling the showerhead 10.

In the case of a PECVD apparatus for forming a Ti layer on a substrate, a power supply rod 45 is electrically connected to the upper surface of the upper plate 10a of the showerhead 10. A high frequency power supply 47 is electrically connected to the power supply rod 45 through a matcher 46. A radio frequency (RF) power is applied from the power supply 47 to the showerhead 10 to generate a high frequency electric field in the chamber 2. Thus, the process gas in the chamber 2 is converted into plasma so that a Ti layer is formed on the semiconductor wafer W. On the contrary, in the case of a thermal decomposition type of CVD apparatus for forming a titanium nitride layer on a substrate, the power supply rod 45, the matcher 46 and the power supply 47 are not provided.

An annular quartz filling member 48 is mounted to the showerhead 10 to prevent plasma from being formed in a space defined by the sides of the upper, middle and lower plates 10a, 10b and 10c, a lower surface of the first insulation member 16, a lower surface of the cover member 15 and the sidewall of the chamber 2. As shown in FIG. 1, the quartz filling member 48 has a concavity 48a in the outer peripheral portion thereof. The quartz filling member 48 is fixed to a supporting member 49 with the concavity 48a of the quartz filling member 48 receiving a convex portion 49a of a supporting member 49. The supporting member 49 is, in turn, fixed to the cover member 15 by screws (not shown) so that the quartz filling member 48 is integrated with the cover member 15.

A gasket (not shown) of an elastic material, such as an elastic material from the fluorine group, is interposed between the filling member 48 and the convex portion 49a of the supporting member 49. The showerhead 10 may be easily centered in the chamber 2 using the gasket (hereinafter “elastic member”). The quartz filling member 48 may be also easily assembled to and disassembled from the chamber 2 using the elastic member. The elastic member prevents the quartz filling member 48 from being damaged due to the expansion and contraction of the showerhead 10. Another elastic member (not shown) is interposed between the quartz filling member 48 and the cover member 15 to prevent the quartz filling member 48 from being damaged.

An exhaust pipe 52 is connected to a sidewall of the stage-supporting member 7 mounted to the chamber 2. An exhaust unit 53 for exhausting gas and byproducts from the chamber 2 is connected to the exhaust pipe 52. A collecting unit (not shown) for collecting the remaining gas or the byproducts may be provided upstream of the exhaust unit 53. The exhaust unit 53 creates a vacuum within the chamber 2.

Furthermore, a shield cover 23 covers the cover member 15. An exhaust port 54 is formed at an upper part of the shield cover 23. Air within the shield cover 23 is exhausted through the exhaust port 54.

Next, the aforementioned showerhead temperature control unit 60 will be described in detail.

The showerhead temperature control unit 60 includes the heater 17 as a heating unit, a first dry air supplying pipe 61a, a second dry air supplying pipe 61b, the heat dissipation plate 18, a temperature detecting unit for detecting the temperature of the lower plate 10d of the showerhead 10, and a controller 62. The temperature detecting unit includes a first thermocouple 65a, a second thermocouple 65b, a third thermocouple 66a, and fourth thermocouple 66b.

The heater 17 is electrically connected to the power supply 63. The first thermocouple 65a contacts the upper plate 10a so as to detect the temperature of the upper plate 10a. The second thermocouple 65b contacts the lower plate 10b so as to detect the temperature of the lower plate. The third and fourth thermocouples 66a and 66b detect the temperatures of the outer peripheral portion of the upper plate 10a and an outer peripheral portion of the lower plate 10c, respectively. Although only one thermocouple may be illustrated for detecting the temperature at a particular portion of the showerhead 10, more than one thermocouple may be alternatively employed as with the case of the second thermocouple 65b, for example.

The showerhead temperature control unit 60 also includes an inner temperature controller 67. The inner temperature controller 67 controls the temperature of the heater 17 in a proportional integral derivative (PID) manner based on feedback from the first and second thermocouples 65a and 65b and a command signal issued by the controller 62. The showerhead temperature control unit 60 further includes an outer temperature controller 68. The outer temperature controller 68 controls the temperature of the heat dissipation plate 18 by controlling the output of the heater 7 in a proportional integral derivative (PID) manner based on feedback from the third and fourth thermocouples 66a and 66b and a command signal issued by the controller 62. Thus, the temperature of the showerhead 10 is precisely controlled by the inner and outer temperature controllers 67 and 68.

The dry air as a coolant provided from the dry air-supplying pipe 61 is introduced into the space 19 through the cooling gas passage 20a in the third insulation member 20. The dry air absorbs heat radiating from the heater 17 into the space 19. The dry air is exhausted from the space through the exhaust hole (not shown) in the third insulation member 20 and is then exhausted from within the shield cover 23 through the exhaust port 54. An air flow control valve 69 is disposed in the dry air-supplying pipe 61. The controller 62 controls the valve 69.

A hinge (not shown) allows the showerhead 10 to be flipped over to the outside of the chamber 2. For example, the hinge pivotally connects the cover member 15 to the chamber 2 such that the cover member 15 and shield cover 23 serve as a lid. Thus, the showerhead 10 may be positioned outside of the chamber 2 with the lower surface of the showerhead 10 facing upwardly so that maintenance may be easily performed on the showerhead 10.

Next, a CVD process of forming a titanium nitride layer on a wafer using the above-described apparatus will be described in detail.

First, the surface of the stage 3 and/or the showerhead 10 is coated before the titanium nitride layer is formed on the semiconductor wafer W.

To this end, power is applied to the heater (not shown) in the chamber 2, the heater 6 in the stage 3, and the heater 17 in the showerhead 10, thereby heating the chamber 2, the stage 3 and the showerhead 10, respectively. In particular, the showerhead 10 is heated to a temperature of at least about 400° C. under the control of the temperature control unit 60. Subsequently, air is exhausted from the chamber 2 by the exhaust unit 53, and then process gas such as H₂, TiCl₄, etc. is introduced into the chamber 2 at a predetermined flow rate via the showerhead 10. RF power is applied to the showerhead 10 from the power supply 47 to generate plasma in the chamber 2, thereby forming a titanium layer on the surface of the showerhead 10 and the stage 3. After the titanium layer is formed on the showerhead 10 and the stage 3, the applying of the RF power to the showerhead 10 and the introducing of the process gas into the chamber 2 are suspended.

Then, a gas such as NH₃ is introduced into the chamber 2 at a predetermined flow rate via the showerhead 10. RF power is again applied to the showerhead 10 from the power supply 47 so that plasma is generated in the chamber 2. The plasma and the titanium react with each other so that a surface of the titanium layer is nitrified. The titanium nitride layer thus formed on the showerhead 10 and the stage 3 is a preliminary coating that remains stable under the conditions in which the wafer W is subsequently processed. After the preliminary coating is formed on the showerhead 10 and the stage 3, the applying of RF power to the showerhead and the introducing of the NH₃ into the chamber 2 are suspended.

Next, a gate valve (not shown) installed in the chamber 2 is opened. The semiconductor wafer W is loaded into the chamber 2 through the gate valve and is mounted on the stage 3. Then the process gas such as H₂, TiCl₄, etc., is introduced into the chamber 2 at a predetermined flow rate via the showerhead 10. RF power is applied to the showerhead 10 from the power supply 47 to generate plasma in the chamber 2, thereby forming a Ti layer on the semiconductor wafer W. After the titanium layer has been formed on the semiconductor wafer W, the applying of the RF power to the showerhead 10 and the introducing of the process gas into the chamber 2 are suspended.

NH₃ is then introduced into the chamber 2 at a predetermined flow rate via the showerhead 10. RF power is applied to the showerhead 10 from the power supply 47 to generate plasma in the chamber 2, thereby nitrifying the titanium layer on the semiconductor wafer W. After the titanium layer is nitrified, the applying of RF power to the showerhead and the introducing of the NH₃ into the chamber 2 are suspended.

Then the semiconductor wafer W is unloaded from the chamber 2 through the gate valve. Another semiconductor wafer to be processed is subsequently loaded into the chamber 2 through the gate valve. The above-mentioned processes are carried out on the new semiconductor wafer to form a titanium nitride layer thereon.

After titanium nitride layers have been formed on a number of semiconductor substrates W, the stage 3 and the showerhead 10 are cooled to a desired temperature, e.g., to temperature of about 200° C. to about 300° C. Then cleaning gas, such as ClF₃, is supplied into the chamber 2 to clean the chamber 2.

The present invention as described above has following advantages.

A titanium layer having a strong adhesive force can be formed on the showerhead 10 because the showerhead 10 can be heated to a temperature of at least about 400° C. On the other hand, the conventional showerhead is indirectly heated by the heater built into the stage. Therefore, the conventional showerhead may not be at a temperature of about 400° C. while the TiCl₄ is introduced into the chamber. In this case, unreacted material such as TiClx (x=1, 2, 3) is generated in the chamber 2. The TiClx has a weak adhesive force. Therefore, the TiClx may flake off of the showerhead and thereby produce particles in the chamber.

Furthermore, according to the present invention, any TiClx can be reduced and nitrified by providing NH₃ gas into the chamber 2. Thus, a preliminary coating having stable characteristics is formed on the showerhead 10.

In addition, the showerhead 10 of the present invention is directly heated by the heater 17 of the temperature control unit 60 as well as the heater 6 in the stage 3. Thus, the entire showerhead 10 may be heated in a relatively short amount of time to stabilize the surface temperature of the lower plate 10c of the showerhead 10. As a result, the temperature in the chamber 2 can be stabilized in a relatively short amount of time. Therefore, a titanium layer having a uniform thickness can be formed on the semiconductor wafer W.

Still further, the temperature of the showerhead 10 can rapidly be lowered to about 200° C. to about 300° C. for cleaning the chamber 2 by supplying dry air from the dry air supplying pipes 61a and 61b to the upper portion of the showerhead 10 using the showerhead temperature control unit 60. On the contrary, the conventional showerhead has a poor heat dissipation characteristic and thus, it takes a long amount of time to lower the temperature of the showerhead.

Temperatures Measured when Using Apparatus of the Present Invention and Conventional Apparatus to Form a Ti Layer on a Wafer

A PECVD apparatus according to the present invention and according to the prior art were used to form a Ti layer on their showerheads. Temperatures of the stage heaters, the showerhead heaters, at the surface of the showerheads, and at the O-rings that sealed the chambers from the external environment were measured and recorded. These temperatures are listed below in Table 1.

TABLE 1

| | | | |
|---|---|---|---|
| | | Surface of the | |
| Stage heater | Showerhead heater | showerhead | O-ring |

(1) Conventional apparatus

| | | | |
|---|---|---|---|
| 530° C. | 300° C. | 360° C. | 401° C. |
| 550° C. | 300° C. | 378° C. | 407° C. |
| 600° C. | 300° C. | 421° C. | 410° C. |

Apparatus of the present invention

| | | | |
|---|---|---|---|
| 530° C. | 300° C. | 360° C. | 199° C. |
| | 320° C. | 378° C. | 200° C. |
| | 350° C. | 403° C. | 204° C. |
| 550° C. | 300° C. | 378° C. | 188° C. |
| | 330° C. | 408° C. | 195° C. |
| | 360° C. | 419° C. | 206° C. |
| 600° C. | 300° C. | 421° C. | 198° C. |

Using the conventional apparatus, the temperature of the surface of the showerhead 10 was raised to about 400° C., by operating the stage heater and the shower heater, so that a titanium layer having a good adhesive force could be formed on the surface of the showerhead. At this time, the showerhead heater had a temperature of about 300° C. and the heater in the stage had a temperature of about 600° C. However, temperature of the O-ring at this time was about 400° C. Therefore, the O-ring deteriorated.

On the contrary, in the apparatus of the present invention, although the heater 6 in the stage 3 and the heater 17 over the showerhead 10 produced a temperature of about 400° C. at the surface of the showerhead 10, the contemporaneous temperature of the O-ring was only about 200° C. because the heat dissipation plate 18 and/or the dry air circulating in space 19 kept the O-ring cool. As a result, the O-ring did not deteriorate.

Temperatures Measured when Using Apparatus of the Present Invention and Conventional Apparatus to Form a TiN Layer on a Wafer

Apparatus according to the present invention and according to the prior art were used to form TiN layers on a wafer. The temperatures of the stage heaters and the temperatures at the surface of the showerheads during the deposition processes were measured and recorded. These temperatures are listed below in Table 2.

TABLE 2

| | | | | | |
|---|---|---|---|---|---|
| Stage heater | 450° C. | 480° C. | 530° C. | 600° C. | 700° C. |
| Conventional | 227° C. | 240° C. | 262° C. | 292° C. | 348° C. |
| Apparatus | | | | | |
| Apparatus of the | 225° C. | 229° C. | 234° C. | 249° C. | 257° C. |
| present invention | | | | | |

As is clear from Table 2, when using the conventional apparatus, the showerhead had a surface temperature of less than 250° C. when the temperature of the stage heater increased to 530° C. or higher. Accordingly, a TiN layer will be formed on the surface of the showerhead and will not adhere well to the showerhead.

On the contrary, in the apparatus of the present invention, even though the temperature of the stage heater 6 was raised to 700° C., the surface temperature of the showerhead 10 did not increase to a temperature substantially greater than about 250° C., because the heat dissipation plate 18 and/or the dry air circulating in space 19 cooled the showerhead 10. Thus, under these circumstances, a layer of TiN would not form on the showerhead.

As described above, the apparatus according to eh present invention controls the temperature of the showerhead using the showerhead heater, the heat dissipation plate and a gas coolant system. Thus, particles will not be produced in the chamber as the result of the deposition of material on the showerhead.

Furthermore, the temperature of an O-ring for sealing a lid of the apparatus is controlled so that the O-ring will not deteriorate. As a result, the chamber is maintained air-tight so that gases will not leak from the chamber nor will the vacuum created in the chamber be compromised.

Although the present invention has been described above in connection with the preferred embodiments thereof, many modifications of the preferred embodiments will be apparent to those skilled in the art. For example, the present invention has been described as applied to apparatus that can form a titanium layer on the surface of the showerhead as a preliminary coating. However, the apparatus may be adapted coat the showerhead with another type of layer serving as a preliminary coating.

Also, the showerhead temperature control unit has been described as using dry air as a coolant to control the temperature of the showerhead. Alternatively, the showerhead temperature control unit may include a source of an inert gas, such as argon or nitrogen, for use as the coolant. Furthermore, when the present invention is applied to a deposition apparatus for forming a layer on a substrate without the use of plasma, the showerhead temperature control unit may include a source of a liquid coolant such as water.

Furthermore, the present invention has been described in connection with apparatus for processing semiconductor wafers. However, the present invention may also be applied to apparatus for processing other types of substrates such as glass substrates of liquid crystal displays (LCDs).

Thus, the foregoing detailed description of the preferred embodiments is illustrative of the present invention and is not to be construed as limiting. Rather, various changes to and modifications of the disclosed embodiments are seen to be within the true spirit and scope of the invention as defined by the following claims.

What is claimed is:

1. The combination of a showerhead that introduces gas into a process chamber, and temperature control apparatus that controls the temperature of the showerhead, wherein the shower head has a bottom plate defining a plurality of spray openings through which gas is sprayed from the showerhead, and the temperature control apparatus comprises a heater disposed on the showerhead, and a heat dissipation plate that contacts a portion the showerhead to absorb heat from the showerhead, said heater being disposed between the bottom plate of the showerhead and the heat dissipation plate.

2. The combination of claim 1, wherein the heat dissipation plate is annular and extends along and contacts an outer peripheral portion of an upper surface of the showerhead.

3. The combination of claim 1, wherein the heat dissipation plate has substantially the form of a disk and contacts substantially the entirety of an upper surface of the showerhead.

4. The combination of claim 1, wherein the heat dissipation plate is of aluminum or an aluminum alloy.

5. The combination of claim 1, wherein a space is defined between the heater and the heat dissipation plate, and the temperature control apparatus further comprises a coolant system including a cooling line extending into the space such that coolant that cools the showerhead can be fed into the space.

6. The combination of claim 5, wherein the coolant includes at least one selected from the group consisting of air, helium, argon, hydrogen and nitrogen.

7. An apparatus for forming a layer on a substrate, comprising:
a processing chamber in which a process of forming a layer on a substrate is performed;
a stage disposed in the processing chamber and on which the substrate to be processed is supported;
a gas supplying unit including a source of a reaction gas used to form the layer;
a showerhead disposed in an upper portion of the processing chamber and connected to the gas supplying unit so as to receive gas therefrom, the shower head having a bottom plate facing the stage and defining a plurality of spray openings through which gas supplied by the gas supplying unit is sprayed from the showerhead;
a first heater disposed on the showerhead so as to heat the showerhead; and
a heat dissipation plate that contacts a portion the showerhead to absorb heat from the showerhead, said first heater being disposed between the bottom plate of the showerhead and the heat dissipation plate.

8. The apparatus of claim 7, further comprising a second heater integrated with the stage to heat a substrate supported by the stage.

9. The apparatus of claim 7, wherein a space is defined between the heater and the heat dissipation plate, and further a coolant system including a cooling line extending into the space such that coolant that cools the showerhead can be fed into the space.
